(19) United States
(12) Patent Application Publication
(10) Pub. No.: US 2010/0213431 A1
(43) Pub. Date: Aug. 26, 2010

(54) Treated Chalcogenide Layer for Semiconductor Devices

(76) Inventors: Tung-Ti Yeh, Tainan City (TW); Chih-Ming Chen, Douliu City (TW); Chung-Yi Yu, Hsin-Chu (TW); Cheng-Yuan Tsai, Chu-Pei City (TW); Neng-Kuo Chen, Sinshih Township (TW); Chia-Shiung Tsai, Hsin-Chu (TW)

Correspondence Address: SLATER & MATSIL, L.L.P., 17950 PRESTON ROAD, SUITE 1000, DALLAS, TX, 75252, US

(21) Appl. No.: 12/617,294

(22) Filed: Nov. 12, 2009

Related U.S. Application Data
(60) Provisional application No. 61/154,127, filed on Feb. 20, 2009.

(51) Int. Cl. H01L 29/24; H01L 21/10

(52) U.S. Cl. 257/2; 438/102; 257/42; 257/E29.1; 257/E21.071

(57) ABSTRACT

A phase change memory and a method of manufacture are provided. The phase change memory includes a layer of phase change material treated to increase the hydrophobic nature of the phase change material. The hydrophobic nature of the phase change material improves adhesion between the phase change material and an overlying mask layer. The phase change material may be treated, for example, with a plasma comprising N₂, NH₃, Ar, He, O₂, H₂, or the like.

This application claims the benefit of U.S. Provisional Application Ser. No. 61/154,127, filed on Feb. 20, 2009, entitled “Treated Chalcogenide Layer for Semiconductor Devices,” which application is hereby incorporated herein by reference.

### TECHNICAL FIELD

The present invention relates generally to semiconductor structures and, more particularly, to semiconductor devices utilizing phase change materials.

### BACKGROUND

Phase change technology is promising for next generation memory devices. It uses chalcogenide semiconductors for storing states and digital information. The chalcogenide semiconductors, also called phase change materials, have a crystalline state and an amorphous state. In the crystalline state, the phase change materials have low resistivity; while in the amorphous state, they have high resistivity. The resistivity ratios of the phase change materials in the amorphous and crystalline states are typically greater than 1000:1, and thus the phase change memory devices are unlikely to have errors for reading states. The chalcogenide semiconductors are stable at a certain temperature range in both crystalline and amorphous states and can be switched back and forth between the two states by electric pulses.

Typically, a phase change memory device is formed by placing a phase change material between two electrodes. Write operations, also called programming operations, which apply electric pulses to the memory device, and read operations, which measure the resistance of the phase change memory, are performed through the two electrodes. Generally, write operations utilize a set pulse and a reset pulse. The set pulse heats the phase change material to a temperature higher than a crystallization temperature, but below a melting temperature, for a time longer than the required crystalline time, for the crystallization to take place. The reset pulse, which turns the phase change material into an amorphous state, heats the phase change material to a temperature higher than the melting temperature. The temperature is then quickly dropped below the crystallization temperature for a time period short enough to reduce or prevent the crystallization. The phase change material is heated by controlling the current flowing through a conductive material, commonly referred to as a “heater.” The heater comprises a conductive material that, due to its resistive properties, heats up when a sufficiently high voltage differential is applied.

A protective layer is often placed over the chalcogenide material to protect the material and to protect surrounding material from damage caused by changing the state of the chalcogenide material. The protective layer, such as a silicon nitride layer, however, does not easily adhere to the chalcogenide material, often resulting in delamination.

One attempt at reducing the delamination is to utilize a buffer or adhesion layer between the chalcogenide and the protective layer. Materials that provide a suitable buffer layer between the chalcogenide and the protective layer are limited and often cause problems during photolithography processes.

Accordingly, there is a need for a protective layer over the phase change material that reduces or eliminates delamination.

### SUMMARY OF THE INVENTION

These and other problems are generally solved or circumvented, and technical advantages are generally achieved, by embodiments of the present invention which provides semiconductor devices using phase change materials.

In accordance with an embodiment of the present invention, a semiconductor device is provided. The semiconductor device includes a phase change layer electrically coupled to a top electrode and a bottom electrode. The phase change layer is formed of a phase change material and has a surface that has been treated to create a more hydrophobic surface. A mask layer is formed over the phase change layer, wherein the mask layer has a higher concentration of silicon atoms along an interface to the phase change layer than an area away from the interface. The treatment may be, for example, a plasma treatment using N₂, NH₃, Ar, He, O₂, H₂, or the like.

In accordance with another embodiment of the present invention, a method of forming a semiconductor device is provided. A phase change layer is formed on one or more dielectric layers, which are on a substrate. At least a surface of the phase change material is treated to cause the surface to become more adhesive. Thereafter, a mask layer is formed over the phase change layer, wherein the mask layer has a concentration of silicon atoms increasing immediately adjacent to the phase change layer. The treatment may be, for example, a plasma treatment using N₂, NH₃, Ar, He, O₂, H₂, or the like.

In accordance with yet another embodiment of the present invention, another method of forming a semiconductor device is provided. A substrate having one or more dielectric layers is provided. A phase change layer is formed over the one or more dielectric layers, and a surface of the phase change layer is modified to be more hydrophobic. The surface of the phase change layer may be modified by, for example, a plasma treatment using N₂, NH₃, Ar, He, O₂, H₂, or the like.

It should be appreciated by those skilled in the art that the conception and specific embodiment disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-5 illustrate a method of forming a phase change memory in accordance with an embodiment of the present invention; and

FIG. 6 is a plot of the composition of the phase change layers with and without treatment in accordance with an embodiment of the present invention.

### DETAILED DESCRIPTION OF ILLUSTRATIVE EMBODIMENTS

The making and using of the present embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

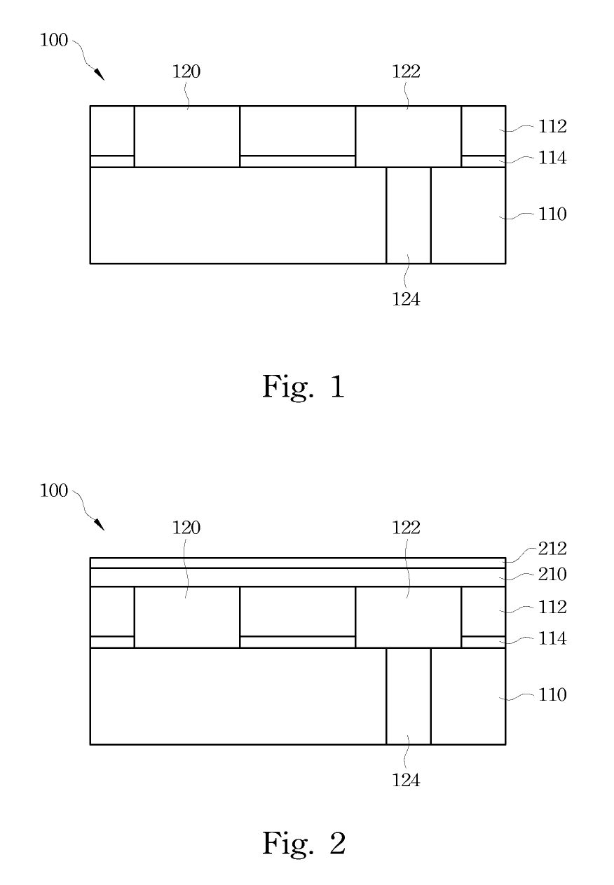

The intermediate stages of manufacturing a novel phase change device embodiment of the present invention are illustrated in FIGS. 1-5. Embodiments of the present invention may be particularly useful in creating phase change memory (PCM) devices. Other embodiments of the present invention, however, may be used in other types of devices. Throughout the various views and illustrative embodiments of the present invention, like reference numerals are used to designate like elements.

Referring first to FIG. 1, a portion of a wafer 100 is shown having a first dielectric layer 110 and a second dielectric layer 112 in accordance with an embodiment of the present invention. The first dielectric layer 110 and the second dielectric layer 112 may be, for example, one or more inter-layer dielectric (ILD) layers and/or inter-metal dielectric (IMD) layers. Generally, the ILD and IMD layers and the associated metallization layers are used to interconnect electrical circuitry (not shown) formed on an underlying substrate (not shown) to each other and to provide an external electrical connection.

The first dielectric layer 110 and the second dielectric layer 112 may be formed, for example, of a low-K dielectric material, such as phosphosilicate glass (PSG), borophosphosilicate glass (BPSG), fluorinated silicate glass (FSG), SiOₓC_{y}, Spin-On-Glass, Spin-On-Polymers, silicon carbon material, compounds thereof, composites thereof, combinations thereof, or the like, by any suitable method known in the art, such as spinning, chemical vapor deposition (CVD), and plasma-enhanced CVD (PECVD). It should be noted that each of the first dielectric layer 110 and the second dielectric layer 112 may comprise a plurality of dielectric layers.

It should also be noted that one or more etch stop layers, such as etch stop layer 114, may be positioned between adjacent ones of the dielectric layers, e.g., between the first dielectric layer 110 and the second dielectric layer 112 as illustrated in FIG. 1. Generally, the etch stop layers provide a mechanism to stop an etching process when forming vias, contacts, or in this case, electrodes. The etch stop layers may be formed of a dielectric material having a different etch selectivity from adjacent layers. In an embodiment, etch stop layers may be formed of SiN, SiCN, SiCO, CN, combinations thereof, or the like, deposited by CVD or PECVD techniques.

A top electrode 120 and a bottom electrode 122 are formed in the second dielectric layer 112. It should be noted that the top electrode 120 and the bottom electrode 122 may be electrically coupled to electronic circuitry (not shown) formed on an underlying substrate (not shown) and/or to an external connection (not shown). The circuitry formed on the substrate may be any type of circuitry suitable for a particular application, such as an access transistor for reading the state of the phase change material and/or changing the state of the phase change material. In an embodiment, the circuitry includes electronic devices formed on the substrate with one or more dielectric layers overlying the electronic devices. Metal layers may be formed between dielectric layers to route electrical signals between the electronic devices. Electrical devices may also be formed in the one or more dielectric layers.

The circuitry may include various N-type metal-oxide semiconductor (NMOS) and/or P-type metal-oxide semiconductor (PMOS) devices, such as transistors, capacitors, resistors, diodes, photo-diodes, fuses, and the like, interconnected to perform one or more functions. The functions may include memory structures, processing structures, sensors, amplifiers, power distribution, input/output circuitry, or the like. One of ordinary skill in the art will appreciate that the above examples are provided for illustrative purposes only to further explain applications of the present invention and are not meant to limit the present invention in any manner. Other circuitry may be used as appropriate for a given application.

For example, in the embodiment illustrated in FIG. 1, the bottom electrode 122 may be electrically coupled to source/drain regions of a transistor formed on an underlying substrate by a contact 124. In this manner, the transistor may be used to control the setting and resetting of the phase change material (to be formed in a subsequent step) and/or reading the state of the phase change material.

The top electrode 120 and the bottom electrode 122 may be formed in the second dielectric layer 112 by any suitable process, including photolithography and etching techniques. Generally, photolithography techniques involve depositing a photoresist material, which is masked, exposed, and developed to expose portions of the second dielectric layer 112 that are to be removed. The remaining photoresist material protects the underlying material from subsequent processing steps, such as etching. In an embodiment, photoresist material is utilized to create a patterned mask to define the top electrode 120 and the bottom electrode 122. Openings may be formed using an etching process such as an anisotropic or isotropic etch process, such as an anisotropic dry etch process. After the etching process, any remaining photoresist material may be removed, and thereafter, the openings may be filled with a conductive material. Processes that may be used to form the top electrode 120 and the bottom electrode 122 include single and dual damascene processes.

The top electrode 120 and the bottom electrode 122 may be formed of any suitable conductive material, such as a highly-conductive, low-resistive metal, elemental metal, transition metal, or the like, including metals or metal alloys including one or more of Al, AlCu, Cu, Ti, TiN, W, and the like. Furthermore, the top electrode 120 and the bottom electrode 122 may include a barrier/adhesion layer to prevent diffusion and provide better adhesion between the top electrode 120/the bottom electrode 122 and the surrounding dielectric layers.

The top electrode 120 and the bottom electrode 122 may be formed, for example, by physical vapor deposition (PVD), atomic layer deposition (ALD), spin-on deposition, or other suitable methods. A chemical-mechanical polishing (CMP) process may be performed to remove excess conductive material and to planarize the surface of the second dielectric layer 112 and the top electrode 120 and the bottom electrode 122.

FIG. 2 illustrates formation of a phase change layer 210 in accordance with an embodiment of the present invention. In an embodiment, the phase change layer 210 comprises chalcogenide materials, such as GeₓSb_{y}Te_{z}, wherein x, y, and z indicate the ratio of the respective numbers. For example, the phase change layer may be formed of Ge₁Sb₄Te₇, Ge₂Sb₂Te₅, Ge₁Sb₂Te₄, or the like. Other materials, such as eutectic Sb₆₉Te₃₁+M, where M is Ag, In, Ge, Sn, or the like, may also be used. In an embodiment, the phase change layer 210 has a thickness of between about 1 nm and about 100 nm, such as between about 5 nm and about 30 nm. The ratio of amorphous resistivity and crystalline resistivity of the phase change layer 210 can be as high as 5 orders, although the ratio may be lower. In an exemplary embodiment, the resistivity of the phase change layer 210 in the amorphous state is between about 1 Ω·cm and about 1E2 Ω·cm, and the resistivity of the same material in the crystalline state is between about 1E-5 Ω·cm and about 5E-3 Ω·cm. In alternative embodiments, phase change materials that can be symbolized as GeₓSb_{y}Te_{z}M are used, wherein M is a material selected from Ag, Sn, In, and combinations thereof.

FIG. 2 further illustrates formation of a treated layer 212 in at least a portion of the phase change layer 210 in accordance with an embodiment of the present invention. It has been found that the materials used to create the phase change layer 210 exhibit a hydrophilic characteristic, and due to this hydrophilic nature, it may be difficult to form an overlying layer with proper adhesion to the phase change layer 210. To increase the adhesion between the phase change layer 210, at least the surface of the phase change layer 210 is treated to modify the hydrophilic nature of the material to have a more hydrophobic tendency. The hydrophobic tendency increases the adhesion of the phase change layer 210 to the overlying layer, thereby reducing or eliminating delamination.

In an embodiment, the treatment comprises an N₂ plasma treatment. For example, the treatment may comprise using a process gas of N₂ and carrier gases of inert gases, He, Ne, Ar, Kr, Xe, and Rn, and combinations thereof. The process conditions may include a temperature lower than the outgassing temperature of the phase change material, such as between about 100° C. and about 300° C., a pressure of between about 1 torr and about 1 torr, an RF power of between about 100 W and about 1000 W, and a process time of between about 10 seconds and about 180 seconds. Other process gases, such as NH₃, Ar, He, O₂, H₂ and the like, may also be used.

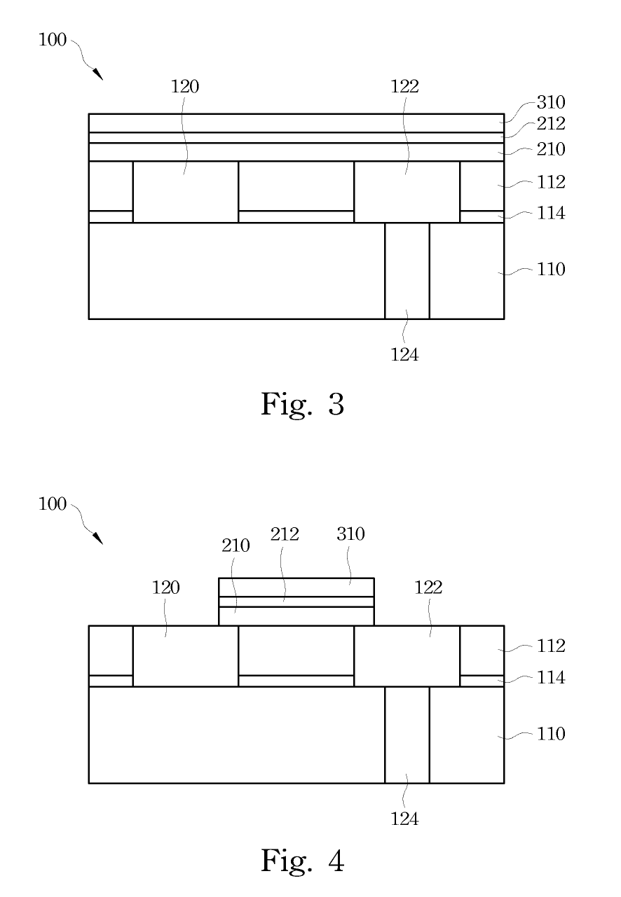

FIG. 3 illustrates the formation of a mask or protective layer 310 formed over the phase change layer 210 and the treated layer 212 in accordance with an embodiment of the present invention. The protective layer 310 provides protection to the overlying materials from the heating of the phase change layer, as well as provides a mask layer during subsequent processing. In an embodiment, the protective layer 310 is a multi-layered mask comprising layers of a nitride layer and an oxide layer. The nitride layer may be a silicon nitride (Si₃N₄) layer formed on top of the oxide layer. The Si₃N₄ layer may be formed using CVD techniques using silane and ammonia as precursor gases, and deposition temperatures ranging from 100° C. to 900° C. The oxide layer may be a silicon dioxide layer formed by thermal oxidation or by CVD techniques using tetra-ethyl-ortho-silicate (TEOS) and oxygen as a precursor. Another nitride layer, such as a silicon oxynitride layer may be formed over the oxide layer. Other types of masks or protective layers, including single-layer masks or multi-layer masks, using the same or other materials, may also be used.

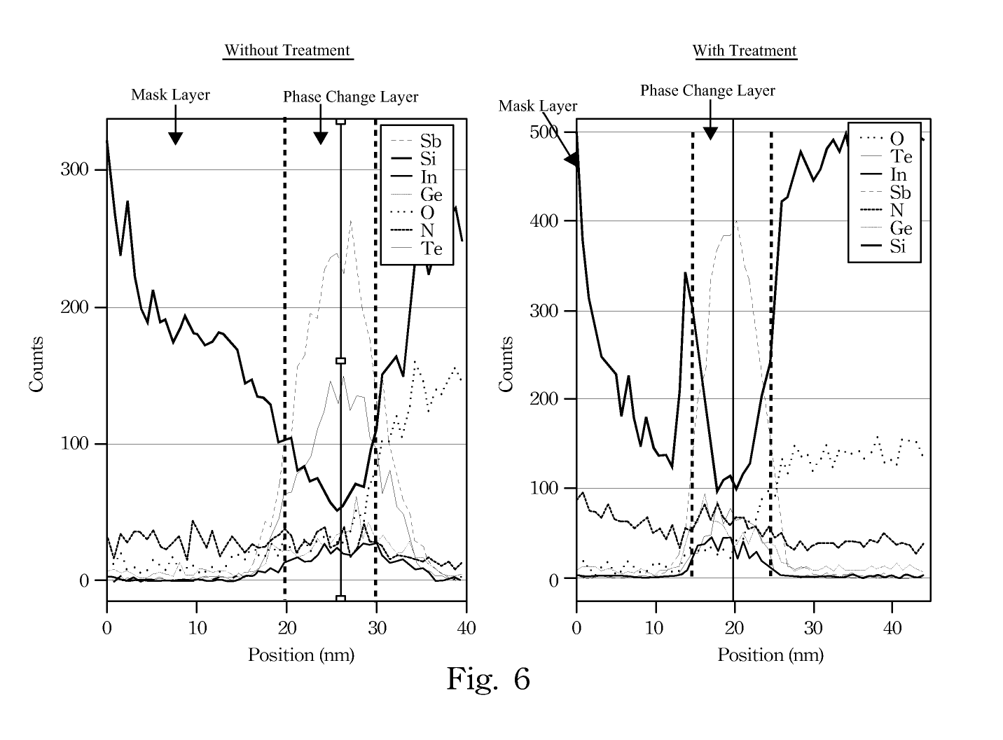

As discussed above, because the treated layer 212 is more hydrophobic than the untreated material of the phase change layer 210, there is greater adhesion between the phase change layer 210 and the protective layer 310, thereby reducing or eliminating delamination between the phase change layer 210 and the protective layer 310. Though the exact cause for modifying the hydrophilic nature of the phase change layer 210 to be more hydrophobic is not fully understood, it has been found that a process such as those discussed above results in a higher concentration of silicon atoms in the protective layer 310 along the interfacial region as illustrated in FIG. 6, which is an EDX analysis of an embodiment of the present invention. It is believed that the treatment to the phase change layer results in a greater attraction to the silicon atoms of the protective layer 310, thereby causing a higher concentration of silicon atoms in the interfacial region than an area of the protective layer 310 further away from the interface, allowing the protective layer 310 to better adhere to the phase change layer 210.

FIG. 4 illustrates the patterning of the phase change layer 210, the treated layer 212, and the protective layer 310. Generally, the phase change layer 210, the treated layer 212, and the protective layer 310 may be patterned using photolithography techniques, such that the phase change layer 210 overlies at least portions of the top electrode 120 and the bottom electrode 122. In this manner, the state of the phase change layer 210 may be controlled and read by placing a voltage differential between the top electrode 120 and the bottom electrode 122. The current flowing through the material of the phase change layer 210 and the resistive properties cause the material of the phase change layer 210 to heat, thereby allowing the material of the phase change layer 210 to be placed in a crystalline state or an amorphous state. The state of the phase change layer 210 may be determined by placing a voltage differential between the top electrode 120 and the bottom electrode 122 and measuring the resistance therebetween.

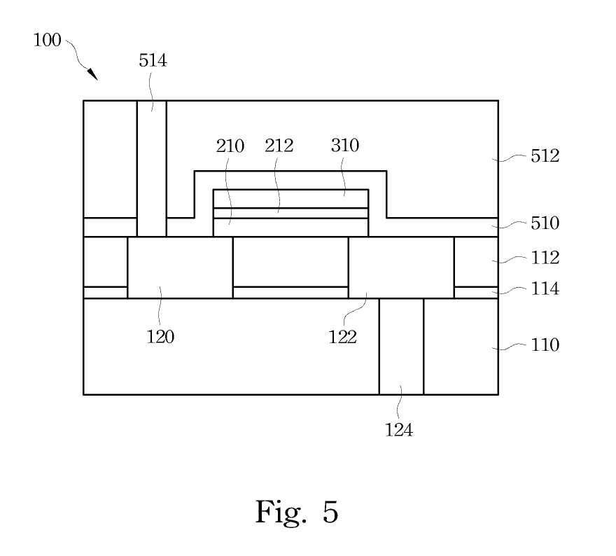

Thereafter, an etch stop layer/sealing layer 510 and a third dielectric layer 512 may be formed in accordance with an embodiment of the present invention as illustrated in FIG. 5. The etch stop layer 510 may be formed, for example, of silicon nitride or other material having a different etch rate than the surrounding materials. In the embodiment in which the protective layer 310 comprises a top layer of silicon oxynitride, it may be desirable to remove the silicon oxynitride layer prior to forming the etch stop layer 510 of silicon nitride. The third dielectric layer 512 may be formed using similar processes and materials as the first dielectric layer 110 and the second dielectric layer 112 discussed above, although it is desirable that materials other than oxygen be used to prevent oxidation of the phase change layer 210. Also shown in FIG. 5 is a contact 514 to the top electrode 120. The contact 514 provides an electrical connection between the top electrode 120 and other circuitry and/or an external contact. The contact 514 may be formed of a conductive material such as metals or metal alloys including one or more of Al, AlCu, Cu, Ti, TiN, W, and the like, using damascene processes.

Although the present invention and its advantages have been described in detail, it should be understood that various changes, substitutions and alterations can be made herein without departing from the spirit and scope of the invention as defined by the appended claims. For example, different types of materials and processes may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a phase change layer electrically coupled to a top electrode and a bottom electrode, the phase change layer comprising a phase change material, wherein a surface of the phase change layer comprises a treated portion; and
a mask layer overlying the phase change layer, the mask layer having a greater concentration of silicon atoms along an interface to the phase change layer than an area away from the interface, the treated portion of the phase change layer having a greater adhesion to the mask layer than untreated phase change material.

2. The semiconductor device of claim 1, wherein the treated portion comprises the phase change material treated with N₂ plasma.

3. The semiconductor device of claim 1, wherein the treated portion comprises the phase change material treated with NH₃, Ar, He, O₂, or H₂ plasma.

4. The semiconductor device of claim 1, wherein the mask layer comprises silicon nitride.

5. The semiconductor device of claim 1, wherein the phase change layer at least partially overlies the top electrode and the bottom electrode.

6. The semiconductor device of claim 1, wherein the phase change material comprises Ge₁Sb₄Te₇, Ge₂Sb₂Te₅, Ge₁Sb₂Te₄, or eutectic Sb₆₉Te₃₁+M, where M is Ag, In, Ge, or Sn.

7. A method of forming a semiconductor device, the method comprising:
providing a substrate having one or more dielectric layers formed thereon;
forming a phase change layer on the one or more dielectric layers;
treating at least a surface of the phase change layer, the treating increasing adhesive properties of the phase change layer; and
forming a mask layer over the phase change layer, a concentration of silicon atoms in the mask layer increasing immediately adjacent to the phase change layer.

8. The method of claim 7, wherein the treating includes at least in part treating the phase change layer with nitrogen, ammonia, argon, helium, oxygen, or hydrogen.

9. The method of claim 7, wherein the treating includes at least in part a plasma treatment.

10. The method of claim 9, wherein the plasma treatment comprises an N₂ plasma treatment, NH₃ plasma treatment, Ar plasma treatment, He plasma treatment, O₂ plasma treatment, or H₂ plasma treatment.

11. The method of claim 7, further comprising forming a top electrode and a bottom electrode in the one or more dielectric layers, and wherein the phase change layer overlies at least a portion of the top electrode and the bottom electrode.

12. The method of claim 7, wherein the mask layer comprises silicon nitride.

13. The method of claim 7, wherein the phase change layer comprises Ge₁Sb₄Te₇, Ge₂Sb₂Te₅, Ge₁Sb₂Te₄, or eutectic Sb₆₉Te₃₁+M, where M is Ag, In, Ge, or Sn.

14. A method of forming a semiconductor device, the method comprising:
providing a substrate having one or more dielectric layers formed thereon;
forming a phase change layer over the one or more dielectric layers;
treating a surface of the phase change layer; and
forming a mask layer over the phase change layer after the treating, wherein the treating increases adhesion of the mask layer to the phase change layer.

15. The method of claim 14, wherein the treating the surface includes at least in part a plasma treatment process.

16. The method of claim 15, wherein the plasma treatment process comprises a N₂ plasma treatment, an NH₃ plasma treatment, an Ar plasma treatment, a He plasma treatment, an O₂ plasma treatment, or an H₂ plasma treatment.

17. The method of claim 14, wherein the mask layer comprises a silicon nitride layer.

18. The method of claim 14, wherein the mask layer comprises a nitrogen-containing layer.

19. The method of claim 14, further comprising forming a top electrode and a bottom electrode in the one or more dielectric layers, wherein the phase change layer is at least partially over the top electrode and the bottom electrode.

20. The method of claim 14, wherein the phase change layer comprises Ge₁Sb₄Te₇, Ge₂Sb₂Te₅, Ge₁Sb₂Te₄, or eutectic Sb₆₉Te₃₁+M, where M is Ag, In, Ge, or Sn.
